(19) United States
(12) Patent Application Publication
(10) Pub. No.: US 2020/0045477 A1
(43) Pub. Date: Feb. 6, 2020

(54) MEMS MICROPHONE

(71) Applicant: AAC Acoustic Technologies (Shenzhen) Co., Ltd., Shenzhen (CN)

(72) Inventors: Yang Bai, Shenzhen (CN); Rui Zhang, Shenzhen (CN)

(21) Appl. No.: 16/524,168

(22) Filed: Jul. 29, 2019

(30) Foreign Application Priority Data
Aug. 2, 2018 (CN) 201821246645.3

(51) Int. Cl. H04R 19/04; H04R 1/04

(52) U.S. Cl. CPC H04R 19/04; H04R 1/04; H04R 2499/11; H04R 2201/003; B81B 2201/0257

(57) ABSTRACT

The present utility model provides a MEMS microphone including a package housing, a substrate forming an accommodation space with the package housing, a MEMS chip accommodated in the accommodation space and having a rear cavity, and an ASIC chip electrically connected with the MEMS chip. The substrate includes an accommodation slot formed in the substrate, and the ASIC chip is accommodated in the accommodation slot and electrically connected with the substrate. In the MEMS microphone provided in the present disclosure, that the ASIC chip is packaged in the substrate avoid corrosion of the ASIC chip caused by direct contact of the ASIC chip and the air, and saves space of the substrate, which facilitate miniaturization of the MEMS microphone.

### TECHNICAL FIELD

The present disclosure relates to the field of electroacoustic transduction technology, and particularly relates to an MEMS microphone applied to a mobile electronic device.

### BACKGROUND

Along with increasingly wide utilization of Micro-Electro-Mechanical System (MEMS) microphones, reliability requirement of packaging MEMS microphone is getting higher and higher, especially to ensure safe operation of a product under harsh conditions, and to protect a product against corrosion in a harmful environment. In the mean time, control over packaging cost is becoming more stringent.

In a related art, a multi-layered substrate and a package housing form a peripheral package of a MEMS microphone device. A peripheral package structure generally has a sound inlet directly connected to the outside. A MEMS chip senses a sound signal from an external environment through the sound inlet, and converts the sound signal into an electrical signal which is to be transmitted to an integrated circuit ASIC chip. A MEMS sensor chip can be connected with the integrated circuit ASIC chip by means of gold wire connection. An ASIC chip can be packaged on the substrate, which takes a substrate space which is hardly sufficient in the first place. What's even worse, impurities in the air corrode an ASIC chip circuit and reduce its electrical performance, causing irreversible damage to a MEMS microphone itself.

Therefore, it is necessary to provide a new MEMS microphone to solve the above-described drawback.

### BRIEF DESCRIPTION OF THE DRAWINGS

In order to describe technical solutions in the embodiments of the present disclosure more clearly, accompanying drawings used to describe the embodiments are briefly illustrated below. It is evident that the drawings in the following description are only concerned with some embodiments of the present disclosure. For those skilled in the art, in a case where no inventive effort is made, other drawings may be obtained based on these drawings.

FIG. 1 is a schematic structural view of a MEMS microphone provided in the present disclosure;

FIG. 2 is a schematic structural view of a substrate as shown in FIG. 1.

### DETAILED DESCRIPTION

The technical solutions in embodiments of the present disclosure will be clearly and completely described with reference to the accompanying drawings of the present disclosure. It is evident that the embodiments described are only some rather than all embodiments of the present disclosure. Based on the embodiments of the present disclosure, all other embodiments obtained by those skilled in the art without making any inventive effort fall into the disclosure of protection by the present disclosure.

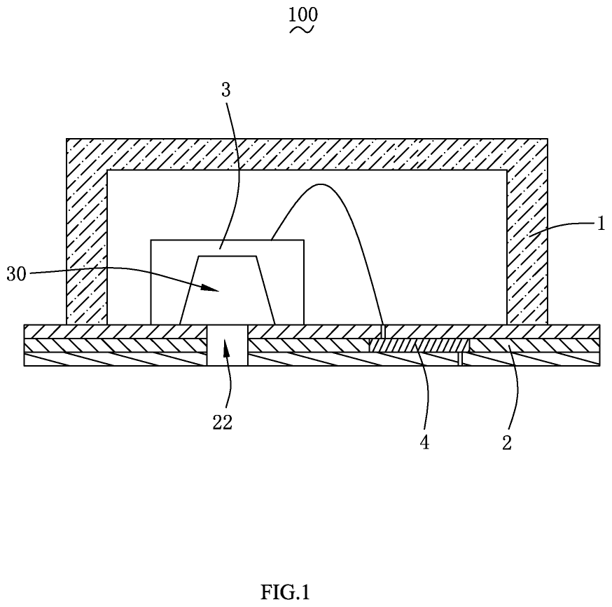

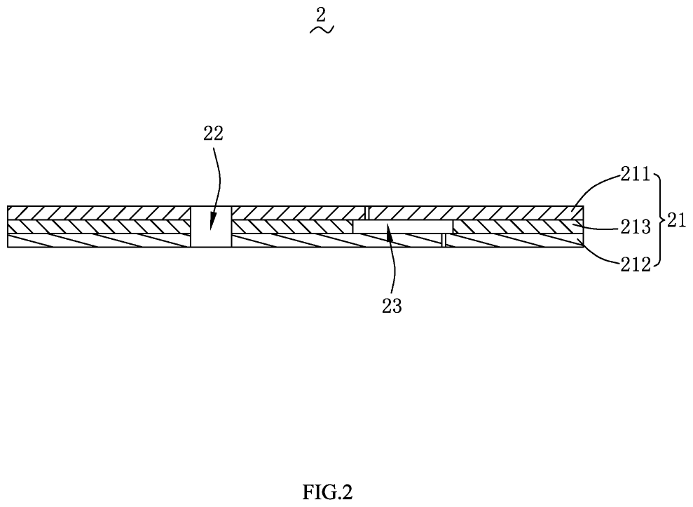

With reference to FIG. 1 and FIG. 2, the present disclosure provides a MEMS microphone 100, including a package housing 1, a substrate 2 forming an accommodation space with the package housing 1, a MEMS chip 3 accommodated in the accommodation space and having a rear cavity 30, and an ASIC chip 4 electrically connected with the MEMS chip 3.

The package housing 1 is a metal housing that can be used for protection. The package housing 1 is configured to perform shielding from an interference signal from the outside.

The substrate 2 is a circuit board configured to electrically connect the MEMS microphone 100 with an outside circuit.

The substrate 2 includes a substrate body 21, a sound inlet 22 penetrated through the substrate body 21, and an accommodation slot 23 formed in the substrate 2. The sound inlet 22 is separated from the accommodation slot 23.

The substrate body 21 includes a first base layer 211, a second base layer 212 provided at a side of the first base layer 211, the side being away from the MEMS chip 3 and the second base layer 212 being separated from the first base layer 211, and a third base layer 213 sandwiched between the first base layer 211 and the second base layer 212, the accommodation slot 23 formed in the third base layer 213.

Preferably, in this embodiment, the substrate body 21 includes three layers. The first base layer 211 is connected with the MEMS chip 3. The third base layer 213 is connected with a side of the first base layer 211, the side being away from the MEMS chip 3. The second base layer 212 is connected with a side of the third base layer 213, the side being away from the first base layer 211.

Specifically, the accommodation slot 23 is formed in the third base layer. The first base layer 211, the second base layer 212 and the third base layer 213 cooperatively form the accommodation slot 23. It is understandable that the first base layer 211 and the second base layer 213 seal the accommodation slot 23, which can effectively prevent impurities in the air from entering the accommodation slot 23. Further, the arrangement of the accommodation slot 23 may save a circuit manufacturing process of the substrate 2 and saving cost thereof.

In another embodiment, the number of layers of the substrate body 21 can be arbitrary, as along as the number of layers meets the condition that the accommodation slot 23 is disposed within the substrate body 21.

The MEMS chip 3 is fixedly connected with the substrate 2. Specifically, the MEMS chip 3 is fixedly connected with the first base layer 211. The MEMS chip 3 is configured to realize conversion of a sound signal to an electrical signal. Specifically, the MEMS chip 3 includes a rear cavity 30 recessing, from a side of the MEMS chip 3 adjacent to the substrate 2, towards a direction away from the substrate 2. The rear cavity 30 is formed through a silicon bulk micromachining or dry-etching. The rear cavity 30 is in communication with the sound inlet 22. A sound signal passes through the sound inlet 22, successively transmits into the rear cavity 30 and drives a diaphragm of the MEMS chip 3 to vibrate, and further, a sound signal is converted to an electrical signal.

The ASIC chip 4 is correspondingly accommodated in the accommodation slot 23, and is electrically connected with the substrate 1. It is understandable that the accommodation slot 23 is a sealed space, which can effectively prevent impurities in the air from entering the accommodation slot 23, thus avoiding corroding the ASIC chip 4 and ensuring electrical performance of the ASIC chip 4.

Specifically, the ASIC chip 4 and the substrate 2 are electrically connected by means of a metalized hole or an inner circuit, which reduces lead bonding when the ASIC chip 4 and the substrate 2 are being connected through a gold wire, thereby reducing a welding process and keeping the structure stable.

Further, the packaging manner of the ASIC chip 4 saves space of the substrate 2 and reduces cost of packaging, which facilitate miniaturization of the MEMS microphone 100.

Compared with a related art, in the MEMS microphone 100 provided in the present disclosure, that the ASIC chip 4 is packaged in the substrate 2 avoid corrosion of the ASIC chip 4 caused by direct contact of the ASIC chip 4 and the air, and saves space of the substrate 2, which facilitate miniaturization requirement of the MEMS microphone 100.

The above-described are only embodiments of the present disclosure. It shall be noted that those skilled in the related art may make improvements without departing from the concept of the present disclosure. All these improvements fall into the protection scope of the present disclosure.

What is claimed is:

1. A MEMS microphone, comprising a package housing, a substrate forming an accommodation space cooperatively with the package housing, a MEMS chip accommodated in the accommodation space and having a rear cavity, and an ASIC chip electrically connected with the MEMS chip, wherein the substrate comprises an accommodation slot formed in the substrate, and the ASIC chip is accommodated in the accommodation slot and electrically connected with the substrate.

2. The MEMS microphone according to claim 1, wherein the MEMS chip is fixed to the substrate.

3. The MEMS microphone according to claim 2, wherein the substrate further comprises a substrate body connected with the MEMS chip and a sound inlet penetrated through the substrate body, and the sound inlet is in communication with the rear cavity of the MEMS and is separated from the accommodation slot.

4. The MEMS microphone according to claim 3, wherein the substrate body comprises a first base layer connected with the MEMS chip, a second base layer provided at a side of the first base layer, the side being away from the MEMS chip and the second base layer being separated from the first base layer, and a third base layer sandwiched between the first base layer and the second base layer, the accommodation slot formed in the third base layer.

5. The MEMS microphone according to claim 4, wherein the first base layer, the second base layer and the third base layer cooperatively form the accommodation slot.

6. The MEMS microphone according to claim 1, wherein the substrate is a circuit board.

7. The MEMS microphone according to claim 1, wherein the ASIC chip and the substrate are electrically connected by a metalized hole or an inner circuit.

8. The MEMS microphone according to claim 1, wherein the MEMS chip and the ASIC chip are electrically connected by a gold wire.

9. The MEMS microphone according to claim 1, wherein the package housing is a metal housing.
